(19) United States
(12) Patent Application Publication
(10) Pub. No.: US 2022/0391970 A1
(43) Pub. Date: Dec. 8, 2022

(54) PRODUCT/SERVICE USE SIMULATION SYSTEM AND COMPUTER PROGRAM PRODUCT

(71) Applicant: KATSUNORI SUETSUGU, TOKYO (JP)

(72) Inventor: KATSUNORI SUETSUGU, TOKYO (JP)

(21) Appl. No.: 17/746,242

(22) Filed: May 17, 2022

(30) Foreign Application Priority Data
Jun. 4, 2021 (JP) 2021-94227

(51) Int. Cl. G06Q 30/06; G06F 30/20

(52) U.S. Cl. CPC G06Q 30/0643; G06F 30/20

(57) ABSTRACT

Provided is a product/service use simulation system and computer program product that are able to simulate a situation in which a user is using a product, a service, or a combination thereof.

The product/service use simulation system includes a user information acquisition unit that acquires user information on a user, a product/service information acquisition unit that acquires product/service information on at least one of a product and a service, a simulation condition setting unit that sets a simulation condition, a simulator that simulates a situation in which the user is using at least one of the product and service, on the basis of the user information, product/service information, and simulation condition, and a simulation result presentation unit that presents the simulation results to the user.

### TECHNICAL FIELD

The present invention relates to a product/service use simulation system and computer program product.

### BACKGROUND ART

Conventionally, when a user purchases a product such as clothing or uses a service, they determine whether to purchase or use it by performing a simulation such as try-on on the basis of the current state or situation, as described in, for example, Japanese Unexamined Patent Application Publication No. 2002-183542. However, when their body shape change, or they run, sunburn, or move to another place, or the product interacts with another product, they have to simulate, in their mind, to what extent the product or service will change.

For example, if a user purchases a T-shirt, they have to predict how they will look like when they become fat somewhat and then wear the T-shirt, to what extent the T-shirt will be durable when they run, to what extent the T-shirt will be quick-dry when they sweat, how the T-shirt will be changed in a harsh weather, to what extent the T-shirt will wear out or endure when they play rugby, which is a hard sport, or the like.

Although these may be shown by descriptions, photos, video, or the like provided by the manufacturer, the user cannot comparatively evaluate products or services or purchase a product or use a service while simulating situations in which each product or service is being used in an environment that is approximately the same as or close to an environment in which the product or service will be actually used. Also, the user cannot simulate situations in which they are using multiple products and services in combination.

For this reason, users have had a risk that they may purchase a product that is not suitable for their need or their future state or situation.

As related art, Japanese Unexamined Patent Application Publication No. 2005-327111 describes a hairstyle display system for performing a simulation of the hairstyle or a comparative simulation indicating the usefulness of products that may be used. This hairstyle display system includes image capture means that captures images of customers, current image data generation means that generates current image data indicating the current hair state of one image-captured customer, image data generation means that generates future image data indicating the hair state of the one customer after a lapse of a predetermined time on the basis of the generated current image data, and display means that displays the generated future image data.

Japanese Unexamined Patent Application Publication No. 2012-133632 describes a technology that generates overall simulation images (video) that move along the progress of a ceremony, by capturing images of content such as a user, clothing, a flower, and a ribbon using a Web camera and a 3D camera, causing the user to select among selectable multiple venues and options such as decorations, combining an image of the selected optional decoration or the like with an image of the selected venue, and placing a combination of the image of the clothing with the image of the user in the venue.

Japanese Unexamined Patent Application Publication Nos. Hei 05-046713 and 2007-011999 describe technologies that simulate a response of a subject to an external force.

Japanese Unexamined Patent Application Publication Nos. 2007-073316 and 2017-219477 describe technologies that simulate the degradation of a subject due to the environment.

See Japanese Unexamined Patent Application Publication Nos. 2002-183542, 2005-327111, 2012-133632, Hei 05-046713, 2007-011999, 2007-073316, and 2017-219477.

### SUMMARY OF INVENTION

The present invention has been made in view of the above problems, and an object thereof is to provide a product/service use simulation system and computer program product that are able to simulate situations in which a user is using a product, a service, or using a combination thereof.

To accomplish the above object, a product/service use simulation system according to the present invention includes a user information acquisition unit configured to acquire user information on a user, a product/service information acquisition unit configured to acquire product/service information on at least one of a product and a service, a simulation condition setting unit configured to set a simulation condition, a simulator configured to simulate a situation in which the user is using at least one of the product and the service, on the basis of the user information acquired by the user information acquisition unit, the product/service information acquired by the product/service information acquisition unit, and the simulation condition set by the simulation condition setting unit, and a simulation result presentation unit configured to present a simulation result obtained by the simulator to the user.

The product/service use simulation system according to the present invention is able to simulate the situation in which the user is using at least one of the product and the service and thus allows the user to check changes caused when the user uses the product or service and helps the user purchase or select the product or service to be used.

In the product/service use simulation system according to the present invention, the user information acquisition unit may acquire physical data indicating a current physical characteristic of the user, and the simulator may simulate how a future physical characteristic of the user will change when the user uses at least one of the product and the service, on the basis of the current physical data of the user.

The product/service use simulation system according to the present invention is able to simulate how the future physical characteristic of the user will change and helps the user purchase or select the product or service.

In the product/service use simulation system according to the present invention, the simulator may simulate a movement of the user who is using at least one of the product and the service.

The product/service use simulation system according to the present invention allows the user to check the movement of the user who is using at least one of the product and the service and helps the user purchase or select the product or service.

In the product/service use simulation system according to the present invention, the simulator may simulate a state in which the product is changing due to application of an external force to the product.

The product/service use simulation system according to the present invention allows the user to check the state in which the product is changing due to application of the external force to the product and helps the user select the product to be purchased.

In the product/service use simulation system according to the present invention, the simulator may simulate a state in which a decorative movement is added to at least one of the product and the service.

The product/service use simulation system according to the present invention allows the user to check the state in which the decorative movement is added to at least one of the product and the service and helps the user purchase or select the product or service.

In the product/service use simulation system according to the present invention, the simulator may simulate how the product is changed by the environment in which the product is placed.

The product/service use simulation system according to the present invention allows the user to check how the product is changed by the environment in which the product is placed and helps the user select the product to be purchased.

A computer program product according to the present invention is a computer program product for causing a computer to function as user information acquisition means configured to acquire user information on a user, product/service information acquisition means configured to acquire product/service information on at least one of a product and a service, simulation condition setting means configured to set a simulation condition, simulation means configured to simulate a situation in which the user is using at least one of the product and the service, on the basis of the user information acquired by the user information acquisition unit, the product/service information acquired by the product/service information acquisition unit, and the simulation condition set by the simulation condition setting unit, and simulation result presentation means configured to present a simulation result obtained by the simulator to the user.

The computer program product according to the present invention is able to simulate the situation in which the user is using at least one of the product and the service and thus allows the user to check changes caused when the user uses the product or service and helps the user purchase or select the product or service to be used.

### BRIEF DESCRIPTION OF DRAWINGS[0022]

FIG. 1 is a diagram showing the overall configuration of a product/service use simulation system according to an embodiment of the present invention; and

FIG. 2 is a diagram showing the functional elements of a control node of the product/service use simulation system according to the embodiment.

### DESCRIPTION OF EMBODIMENTS

Now, an embodiment of the present invention will be described in detail with reference to the drawings.

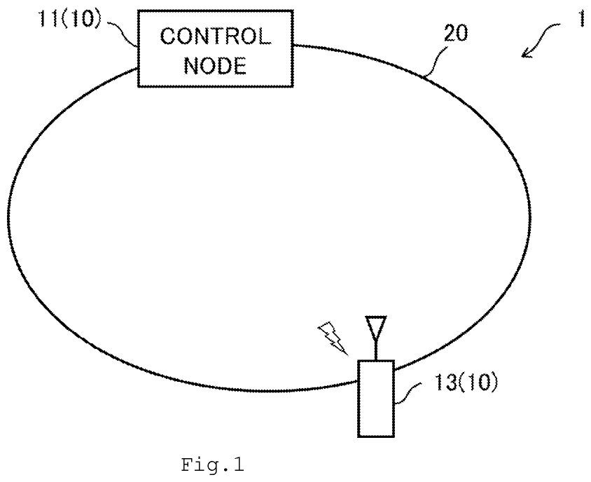

FIG. 1 is a diagram showing the overall configuration of a product/service use simulation system 1 according to an embodiment of the present invention. As shown in FIG. 1, the product/service use simulation system 1 includes multiple nodes 10 forming a blockchain network 20. The nodes 10 include a control node 11 that controls the entire system 1 and a user terminal 13 owned by a user and are configured to be able to communicate with each other through the blockchain network 20. The user terminal 13 is, for example, a communication terminal such as a personal computer or portable information terminal.

The control node 11 is a computer having a communication function and includes, as hardware, a CPU, a storage device including RAM, ROM, and hard disk, a communication interface that controls communication through the blockchain network 20, and input/output interfaces such as a keyboard and a display. Software such as various types of data, databases and programs are stored in the storage device of the control node 11. Examples of the data stored in the storage device of the control node 11 include user information on users, product/service information on products and services, simulation conditions, and various types of learning data required to perform simulations. Examples of the learning data include data for simulating what extent an automobile as a product tends to be contaminated or damaged by a predetermined environment, what extent the cleanliness of the automobile can be maintained with what extent of the user's care for the automobile.

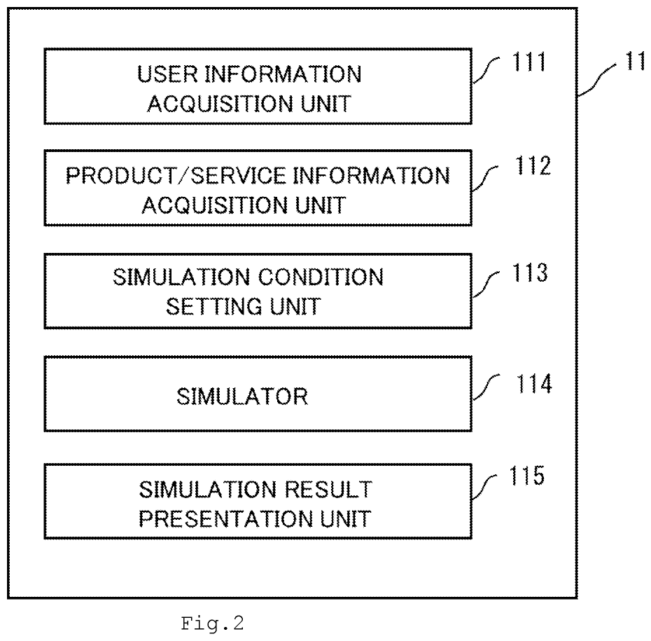

Examples of the programs stored in the storage device of the control node 11 include a program for simulating situations in which a user is using a product or service and a program for presenting the simulation results to the user. When the CPU of the control node 11 performs processing in accordance with the software stored in the storage device, functional elements shown in FIG. 2 are implemented on the control node 11.

A user information acquisition unit 111 acquires user information on a user. For example, the user information acquisition unit 111 acquires the user information from a database on the storage device. Examples of the user information include physical data indicating the current physical characteristics of the user (the height, weight, abdominal girth, chest circumference, skin color, hair length, and the like of the user), the daily behavior, exercise, and meal patterns of the user, the past behavior, exercise, and meal histories of the user, and the like. The user information may be acquired from a database previously inputted and registered by the user, or may be acquired by the camera or sensor of the user terminal 13, or may be inputted to the user terminal 13 by the user each time the user takes a meal or does exercise.

A product/service information acquisition unit 112 acquires product/service information on the product or service with respect to which the user wants a simulation before actually purchasing or using it. Examples of the product/service information include information on clothing, an automobile, an umbrella, a shelf, a carpet, a cup, a smartphone, a personal computer, a beauty service, a barber service, travel, and a tour. The product/service information may be provided from a vendor that sells or produces the product or a provider that provides the service, or may be acquired from a database owned by the vendor or provider.

A simulation condition setting unit 113 sets a simulation condition on the basis of specification input by the user or on the basis of conditions previously determined by the product/service use simulation system 1.

Examples of the simulation condition include a simulation of changes in the product or user associated with a lapse of a predetermined time after the start of use of the product or service, a simulation of changes in the product in a predetermined environment, a simulation of changes in the product due to application of a predetermined external force to the product, and a simulation of changes in the user due to use of the product or service based on the daily behavior pattern of the user. For example, if the product is a wig, the simulation condition setting unit 113 sets a simulation of the resistance to typhoon or strong wind of the wig worn by the user. If the service is an event service, the simulation condition setting unit 113 sets a simulation of a state in which a decoration is added to the event venue. If the product is an automobile, the simulation condition setting unit 113 sets a simulation of changes in the automobile in a predetermined environment.

A simulator 114 performs simulations according to the various types of learning data stored in the storage device of the control node 11.

More specifically, a simulator 114 simulates a situation in which the user is using the product, service, or a combination thereof, on the basis of the user information acquired by the user information acquisition unit 111, the product/service information acquired by the product/service information acquisition unit 112, and the simulation condition set by the simulation condition setting unit 113.

For example, the simulator 114 simulates how the future physical characteristics of the user will change from the current state due to use of the product or service by the user. As a more specific example, the simulator 114 simulates physical changes in the user such as growth of the hair, an increase in height, an increase or reduction in weight, darkening of the skin color due to sunburn, an increase in muscle mass, or an increase in fat mass.

Thus, for example, if a user on a diet is considering the purchase of clothing that does not currently fit the user and that is specified by the user as a simulation condition, the simulator 114 is able to simulate how many months later the clothing will fit the user best due to the progress of the diet and thus weight reduction at the current pace by using a diet service or an exercise service. Conversely, if a sumo wrestler or athlete wants to increase the body size by increasing the weight or muscle mass, the simulator 114 is able to simulate how many days later the clothing will fit the sumo wrestler or the like best due to an increase in body size at a predetermined pace by using a weight increase service or an exercise service.

The simulator 114 is also able to simulate a movement of the user who is using the product or service.

Specifically, for example, the simulator 114 is able to simulate a situation in which the user wearing a soccer uniform is repeating a typical movement in soccer. The simulator 114 is also able to simulate a situation in which the user using mountain climbing goods selected by them is doing a typical behavior in mountain climbing. The simulator 114 is also able to simulate a typical behavior of the user in daily life. If the user uses the product or service for business, the simulator 114 is able to simulate a typical behavior, or a behavior specific to the user or job category.

The simulator 114 is able to simulate changes in the product due to application of an external force to the product.

For example, if the product is a ballpoint pen, the simulator 114 is able to simulate changes in the ballpoint pen due to removal of a cap therefrom or attachment of a cover thereto. If the product is an automobile, the simulator 114 is able to simulate changes in the automobile due to travel thereof or creation of a carriage space in the rear seat thereof.

If the product is reversible clothing, the simulator 114 is able to simulate a reversed state of the clothing. If the product is a folding bag, the simulator 114 is able to demonstrate a simulation of a method for folding the folding bag. If the product is a notebook personal computer, the simulator 114 is able to demonstrate opening and closing of the lid thereof. The simulator 114 is also able to demonstrate the swelling degree, appearance, or the like of a pocket of the clothing in which the notebook personal computer is put. If the product is workwear used at a building site, the simulator 114 is able to simulate to what extent the workwear will be contaminated, to what extent the fibers or the like of the workwear will wear out, or the like while taking into consideration the characteristics of the site, aging degradation, or the like. If the user plays rugby, the simulator 114 is able to reproduce a rugby match and to simulate a situation in which clothing is worn out by an external force from an actual opponent team player or the like or contaminated by dirt. At this time, the simulator 114 is able to simulate to what extent the shape, color, fibers, or the like of the clothing will change with the number of matches or the frequency of practice. More specifically, the simulator 114 is able to simulate to what extent three-times-per-week practice for half a year or four-times-per-week practice for one year will influence the clothing, that is, the durability, design, the sign of wear, or the like of the clothing. If the product is an umbrella, the simulator 114 is able to simulate to what extent the umbrella can be broken or deformed at the time of strong wind or typhoon, whether the umbrella suffers wear-out, color change, or the like, whether the umbrella is easy to use for the user, or the like. If the product is a wig, the simulator 114 is able to simulate the resistance to typhoon or strong wind of the wig worn by the user, or the like. If the product is a glass cup, the simulator 114 is able to simulate temporal changes or aging degradation of the cup. For example, the simulator 114 is able to simulate approximately when the cup will come to cloud due to every day drinking of milk or vegetable juice using the cup.

The simulator 114 is also able to simulate a state in which a decorative movement or a decoration is added to the product or service.

Specifically, if the product is a pencil, the simulator 114 is able to simulate a state in which a cap is attached to the pencil. If the product is a smartphone, the simulator 114 is able to simulate a state in which a cover is attached to the smartphone. If the product is a personal computer, the simulator 114 is able to simulate a state in which a cover is attached to the personal computer or the coating of the personal computer is changed. If the product is an automobile, the simulator 114 is able to simulate a state in which an optional part or additional part is attached to the automobile. If the service is an event service, the simulator 114 is able to simulate a state in which a decoration is added to the venue.

In addition to decoration using an object, the simulator 114 is able to simulate a state in which a “decorative movement as an event” is added to the product or service. For example, if the service is a theme park such as an amusement park, a parade made in the theme part is an added “decorative movement.” Also, if a mascot character appears in the venue, the appearance is an added “decorative action.” If the service is travel or tour sponsored by a travel agency, an event or the like performed in this travel or tour is an added “decorative action.”

The simulator 114 is also able to simulate how the product is changed by the environment in which the product is placed.

For example, if the product is a parasol, the simulator 114 is able to simulate how the parasol will function at the latitude, weather, region, or the like. The simulator 114 is also able to simulate whether one product can degrade earlier when it is used in a tropical region, where the sunlight is strong, than when it is used in a warm place. If the product is underwear, the simulator 114 is able to simulate how much time of action in what region in summer of the user wearing the underwear will cause the user to come to worry about the smell of sweat. If the product is eyeglasses, the simulator 114 is able to simulate how many minutes later the eyeglasses worn by a user will begin to slide down, what degree of a tightened feeling or comfort the user wearing the eyeglasses will feel, or the like. The simulator 114 is also able to simulate to what extent the lenses will be clouded by nose breath when the user wears the eyeglasses while wearing a mask. If the product is an automobile, the simulator 114 is able to simulate to what extent the automobile tends to be contaminated or damaged by the environment, to what extent the cleanliness of the automobile can be maintained with what extent of the user's care for the automobile, or the like. The simulator 114 is also able to simulate to what extent the automobile will wear out with what extent of offroad travel.

A simulation result presentation unit 115 presents the simulation results obtained by the simulator 114 to the user.

Methods for presenting to the user include displaying the simulation results on the display of the user terminal 13 as a three-dimensional image, displaying them on a large display installed in a real store, and presenting them using a technology such as VR, AR, or hologram.

As seen above, in the product/service use simulation system 1, the simulator 114 simulates the situation in which the user is using the product, service, or combination thereof, on the basis of the user information, product/service information, and simulation condition, and the simulation result presentation unit 115 presents the simulation results to the user. Thus, the user is able to check the situation in which the user is actually using the product, service, or combination thereof or check changes in the product or the like. That is, the user is able to perform a simulation that the user conventionally performs in their head at the time of purchase while checking an computer-processed image. As a result, the user is able to easily make a purchase without troubling their head excessively, on the basis of comparative evaluation of the simulation results.

Specifically, for example, if the product is a bookshelf, the user is able to consider the purchase while simulating how many documents, books, or the like the bookshelf can accommodate. If the product is a chest of drawers, the user is able to consider the purchase while simulating how many articles or the like the chest of drawers can accommodate.

If the products are a carpet, cover, curtain, furniture, or the like, the user is able to consider the purchase while checking whether the products will fall within the dimensions of an actual room or checking their movements with respect to each other. The user is also able to consider the purchase while simulating aging degradation or the like.

The user is also able to simulate whether a smartphone, purse, notebook personal computer, or the like will be put into a pocket attached to the clothing or how the smartphone or the like will be put into the pocket.

The user is also able to simulate a burden on their body caused by pressing of the body by the clothing. For example, the user is able to simulate the degree of stress, comfort, or the like felt by the user wearing tight clothing that looks good but strongly presses the body. Conversely, the user is also able to simulate the ease of movement of the user wearing tight clothing to actively move in a sport or the like and simulate changes in the body of the user in such a state.

The user is also able to simulate to what extent the user will change by eating food. By registering the daily behavior pattern of the user, the amount of exercise, an irregular, sudden motion, and the like can also be included as simulation conditions. Thus, the user is able to simulate how much calorie the user will totally consume. Moreover, the user is able to simulate changes in the body shape, the tension of the skin, the degree of tension of the body, how muscle will be built, how fat will be built, or the like, as well as is able to simulate changes in the body shape due to meals, the daily life, exercise, or the like. The user is also able to check an image indicating the body shape, which is the simulation results, and to select food or meal with reference to the image.

The user is also able to simulate how the body shape of the user will change due to addition or reduction of a certain meal to or from the previously registered user information such as the daily behavior, exercise, or meal pattern of the user and thus to use this system 1 also for diet or health maintenance.

The user is also able to simulate how the body shape will change when the user performs particular exercise, muscle training, or meal control with respect to the daily situation of the user. Thus, the user is able to simulate what amount of meal, what amount of supplementary food such as protein, or what amount of exercise is most suitable for the goal or ideal life of the user. Also, when the user uses an exercise service, this system 1 helps the user comparatively evaluate exercise services. For example, the user is able to comparatively evaluate details of exercise services while simulating the motions or the like of each exercise service. This system 1 also helps the user, for example, determine which of use of a sports gym for one hour twice a week and use thereof for two hours once a week is more suitable for the user.

The user is also able to simulate changes in the body shape caused by intake energy and consumption energy or the like in the daily life pattern such as work, play, meal, exercise, and sleep. For example, the user is able to simulate how the body shape will change if, in a long business trip for about half a year from now on, the user changes the lifestyle from night-oriented to morning-oriented, changes their eating habits, and loses physical strength due to commuting or work.

When the user has a beauty shop, barber shop, or the like cut or design their hair, they are able to check whether the hairstyle or set is most suitable for their behavior pattern. The user is also able to receive services of the beauty shop or barber shop while checking simulations as to what extent the hair will grow for the coming three months, how the hair tends to change due to high humidity in the rainy season, how the hair tends to change in winter, how the hairstyle tends to change in a dry region, or the like. The user is also able to simulate how the hair will change when they use a hairstyling product for business while checking the differences between hairstyles based on the types of hairstyling products. The user is also able to simulate how the hairstyle will change when they have their hair permed or colored. Also, with respect to the same hair, the user is able to simulate the yet-to-be-styled hair, the hair of the user who is relaxing home, or the bed hair of the user who has just got up. Thus, the user is able to determine details of services of the beauty shop or barber shop while checking these simulation results.

The above embodiment is illustrative only, and various modifications can be made to the present invention without departing from the spirit and scope of the invention set forth in the claims.

For example, the communication system of the product/service use simulation system 1 is not limited to the blockchain network 20 in the above embodiment and may be, for example, pier-to-pier (P2P) communication, client-server communication, communication using a distributed storage blockchain, or a combination thereof.

While, in the above embodiment, the product/service use simulation system 1 has been described as including the multiple nodes 10, the product/service use simulation system 1 is not limited to this device configuration. For example, the product/service use simulation system 1 may consist of a single device or a client-server system. If the product/service use simulation system 1 consists of a single device, this device may be a stand-alone device, which is not connected to a network such as the Internet.

What is claimed is:

1. A product/service use simulation system comprising:
a user information acquisition unit configured to acquire user information on a user;
a product/service information acquisition unit configured to acquire product/service information on at least one of a product and a service;
a simulation condition setting unit configured to set a simulation condition;
a simulator configured to simulate a situation in which the user is using at least one of the product and the service, on the basis of the user information acquired by the user information acquisition unit, the product/service information acquired by the product/service information acquisition unit, and the simulation condition set by the simulation condition setting unit; and
a simulation result presentation unit configured to present a simulation result obtained by the simulator to the user.

2. The product/service use simulation system of claim 1,
wherein the user information acquisition unit acquires physical data indicating a current physical characteristic of the user, and
wherein the simulator simulates how a future physical characteristic of the user will change when the user uses at least one of the product and the service, on the basis of the current physical data of the user.

3. The product/service use simulation system of claim 1, wherein
the simulator simulates a movement of the user who is using at least one of the product and the service.

4. The product/service use simulation system of claim 1, wherein
the simulator simulates a state in which the product is changing due to application of an external force to the product.

5. The product/service use simulation system of claim 1, wherein
the simulator simulates a state in which a decorative movement is added to at least one of the product and the service.

6. The product/service use simulation system of claim 1, wherein
the simulator simulates how the product will be changed by an environment in which the product is placed.

7. A computer program product for causing a computer to function as:
user information acquisition means configured to acquire user information on a user;
product/service information acquisition means configured to acquire product/service information on at least one of a product and a service;
simulation condition setting means configured to set a simulation condition;
simulation means configured to simulate a situation in which the user is using at least one of the product and the service, on the basis of the user information acquired by the user information acquisition unit, the product/service information acquired by the product/service information acquisition unit, and the simulation condition set by the simulation condition setting unit; and
simulation result presentation means configured to present a simulation result obtained by the simulator to the user.
